(19) United States
(12) Patent Application Publication
(10) Pub. No.: US 2020/0295038 A1
(43) Pub. Date: Sep. 17, 2020

(54) VOLTAGE-VARIABLE TYPE MEMORY ELEMENT AND SEMICONDUCTOR MEMORY DEVICE HAVING THE SAME

(71) Applicant: Toshiba Memory Corporation, Minato-ku (JP)

(72) Inventors: Takao SUEYAMA, Yokohama (JP); Keiko KANEDA, Chiba (JP); Masahiro SHIMURA, Yokohama (JP); Kaori KAWASAKI, Yokohama (JP)

(73) Assignee: Toshiba Memory Corporation, Minato-ku (JP)

(21) Appl. No.: 16/568,645

(22) Filed: Sep. 12, 2019

(30) Foreign Application Priority Data
Mar. 11, 2019 (JP) 2019-043432

(51) Int. Cl. H01L 27/11582; G11C 16/10; G11C 16/04

(52) U.S. Cl. CPC H01L 27/11582; G11C 16/0483; G11C 16/10

(57) ABSTRACT

A voltage-variable type memory element having an electrode; a charge storage layer that is arranged on the electrode via a first interlayer insulating layer and stores charges; and a semiconductor wiring which has electric conductivity, that is arranged on the charge storage layer via a second interlayer insulating layer, and comprises a region facing the charge storage layer, a resistance value of the region being variable according to magnitude of potential corresponding to an amount of charges stored in the charge storage layer, and a voltage value of a reading signal supplied and passing through the semiconductor wiring being varied according to the resistance value. A semiconductor memory device configure to a memory cell array in which voltage-variable type memory elements are arranged as memory cells.

### CROSS-REFERENCE TO RELATED APPLICATIONS

This application is based upon and claims the benefit of priority from Japanese Patent Application No. 2019-043432, filed Mar. 11, 2019, the entire contents of which are incorporated herein by reference.

### FIELD

Embodiments relate to a voltage-variable type memory element and a semiconductor memory device having the same.

### BACKGROUND

A semiconductor memory device comprises nonvolatile semiconductor memory elements arranged in a matrix form.

Embodiments provide a semiconductor memory device comprising a voltage-variable type memory element that reads stored information by using a voltage variation caused by change of a resistance value of a semiconductor wiring.

### BRIEF DESCRIPTION OF THE DRAWINGS

FIG. 1 is a diagram showing a conceptual cross-sectional structure of a voltage-variable type memory element according to a first embodiment;

FIG. 2A is a diagram showing an arrangement example of an electrode which is arranged so as to face a semiconductor wiring through an interlayer insulating layer in proximity to the semiconductor wiring;

FIG. 2B is a cross-sectional view explaining reduction in resistance value of a partial region of the semiconductor wiring caused by application of a positive voltage;

FIG. 2C is a cross-sectional view explaining increase in resistance value of a partial region of the semiconductor wiring caused by application of a negative voltage;

FIG. 3 is a diagram showing change in the resistance value of the semiconductor wiring with respect to an applied voltage in the voltage-variable type memory element;

FIG. 4 is a diagram showing change in resistivity of the semiconductor wiring with respect to an applied voltage in the voltage-variable type memory element;

FIG. 5 is a cross-sectional view explaining writing of data into the voltage-variable type memory element;

FIG. 6 is a cross-sectional view explaining erasure of data from the voltage-variable type memory element;

FIG. 7A is a diagram showing a state where a wiring region of the semiconductor wiring has a high resistance value when a charge storage layer is at a negative potential and the potential of the electrode is in a floating state;

FIG. 7B is a diagram showing a state where the wiring region of the semiconductor wiring has a low resistance value when the charge storage layer is at a negative potential and a positive voltage is applied to the electrode;

FIG. 8A is a diagram showing a state where the wiring region of the semiconductor wiring is reduced in resistance value when the charge storage layer is at a positive potential and the potential of the electrode is in a floating state;

FIG. 8B is a diagram showing a state where the wiring region of the semiconductor wiring has a low resistance value when the charge storage layer is at a positive potential and a positive voltage is applied to the electrode;

FIG. 9 is a diagram showing functional blocks of a semiconductor memory device comprising a voltage-variable type memory element according to a second embodiment;

FIG. 10 is a diagram showing a circuit configuration of a memory cell array;

FIG. 11 is a diagram conceptually showing a lamination structure of the memory cell array;

FIG. 12 is a diagram explaining reading of data from memory cells when data are stored;

FIG. 13 is a diagram explaining reading of data from the memory cells when data are not stored; and

FIG. 14 is a diagram explaining reading of data from the memory cells.

### DETAILED DESCRIPTION

Embodiments will be described hereunder with reference to the drawings.

The embodiments illustrate devices for embodying the technical idea of the invention. The drawings are schematic or conceptual, and the dimensions, proportions, etc. of the respective drawings are not necessarily the same as the actual ones. Furthermore, the technical idea of the present invention is not specified by the shapes, structures, arrangements and the like of components. Note that in the following description, the components having substantially the same functions and configurations are represented by the same reference signs, and detailed descriptions thereof will be omitted.

A voltage-variable type memory according to the embodiments is formed in a lamination structure comprising an electrode, a charge storage layer that is arranged on one main surface side (for example, a lower surface side) of the electrode through a first interlayer insulating layer and stores charges, and a semiconductor wiring having electric conductivity and that is arranged on the charge storage layer through a second interlayer insulating layer. In the semiconductor wiring, the resistance value of a region facing the charge storage layer is variable depending on the magnitude of potential which corresponds to storage or non-storage of memory information (or data), that is, the amount of charges stored in the charge storage layer. The voltage value of a data estimation signal for determining storage or non-storage of data passing through the semiconductor wiring changes in accordance with the resistance value. The voltage-variable type memory according to the embodiments does not read out data itself stored in a memory cell, but determines whether data is stored in the memory cell, based on the signal level (magnitude level) of a data estimation signal which has passed by the memory cell and varied in voltage value due to the presence or absence of data in the memory cell.

### First Embodiment

A voltage-variable type memory element using change in resistance value of the semiconductor wiring will be described as a first embodiment. FIG. 1 is a diagram showing a conceptual cross-sectional structure of the voltage-variable type memory element (MC) according to the present embodiment.

The voltage-variable type memory element 1 is configured by a semiconductor wiring 2, a charge storage layer 3 that stores (accumulates or charges) information as charges, an electrode 4, and an interlayer insulating layer 5.

The interlayer insulating layer 5 electrically separates the charge storage layer 3 and the electrode 4 from each other. In other words, the voltage-variable type memory element 1 is configured that the semiconductor wiring 2, the charge storage layer 3, and the electrode 4 form a lamination structure, and further these components are electrically separated from one another by the interlayer insulating layer 5. Here, the electrode 4 is referred to as a first layer, the charge storage layer 3 is referred to as a second layer, and the semiconductor wiring 2 is referred to as a third layer. As described later, data read out from the voltage-variable type memory element 1 is amplified and output by a sense amplifier 6 provided outside. The charge storage layer 3 does not establish wiring connection with other components, and is formed in an island-like shape in an electrically floating state. The charge storage layer 3 can be formed of, for example, various conductors including polycrystalline silicon, that is, polysilicon (Poly silicon).

In the following description, the amount of charges or voltage value stored in the charge storage layer 3 is referred to as potential. When a preset reference potential is set to, for example, 0 V, a potential higher than the reference potential is referred to as a positive potential, and a potential lower than the reference potential is referred to as a negative potential.

The voltage-variable type memory element 1 corresponds to a memory cell (MC). The semiconductor wiring 2 is formed of polysilicon as a main material which has been reduced in resistance by processing of doping impurities or the like.

The interlayer insulating layer 5 is formed of, for example, a silicon oxide film. In the interlayer insulating layer 5 of the present embodiment, an interlayer insulating layer 5a (second interlayer insulating film) is formed between the semiconductor wiring 2 and the charge storage layer 3, and an interlayer insulating layer 5b [first interlayer insulating film] is formed between the electrode 4 and the charge storage layer 3.

In the present embodiment, writing (charging) and erasure (discharging) of charges from the electrode 4 to the charge storage layer 3 are performed through the interlayer insulating layer 5b. In other words, writing (charging) and erasure (discharging) are performed between the electrode 4 and the charge storage layer 3. The thickness of the interlayer insulating layer 5b is set to such a film thickness that charges stored in the charge storage layer 3 do not leak to the electrode 4 side and data can be written and erased by charges. The thickness of the interlayer insulating layer 5a is set to such a film thickness that charges stored in the charge storage layer 3 do not leak to the semiconductor wiring 2 side and the stored charges can change the resistance value of the semiconductor wiring 2. These film thicknesses are appropriately set according to a semiconductor material to be used, the concentration of impurities, the magnitude (voltage) of a signal value based on the design, and the like.

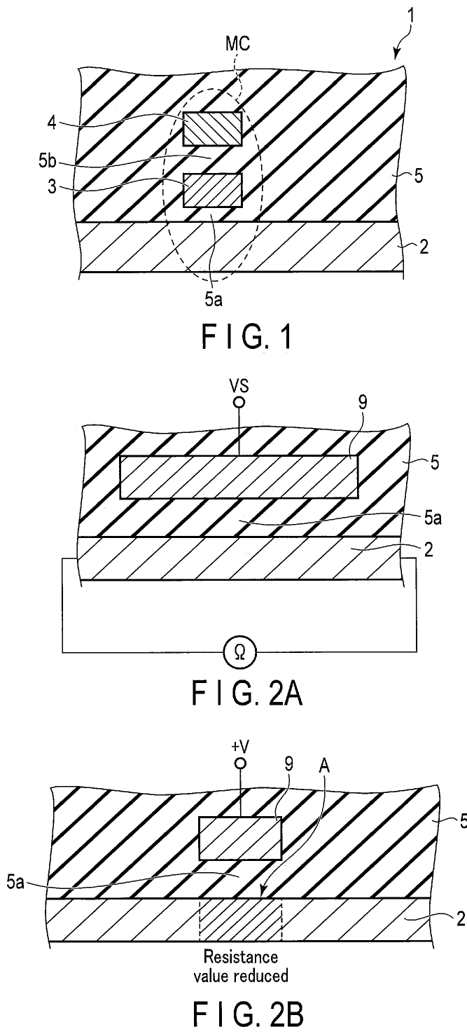

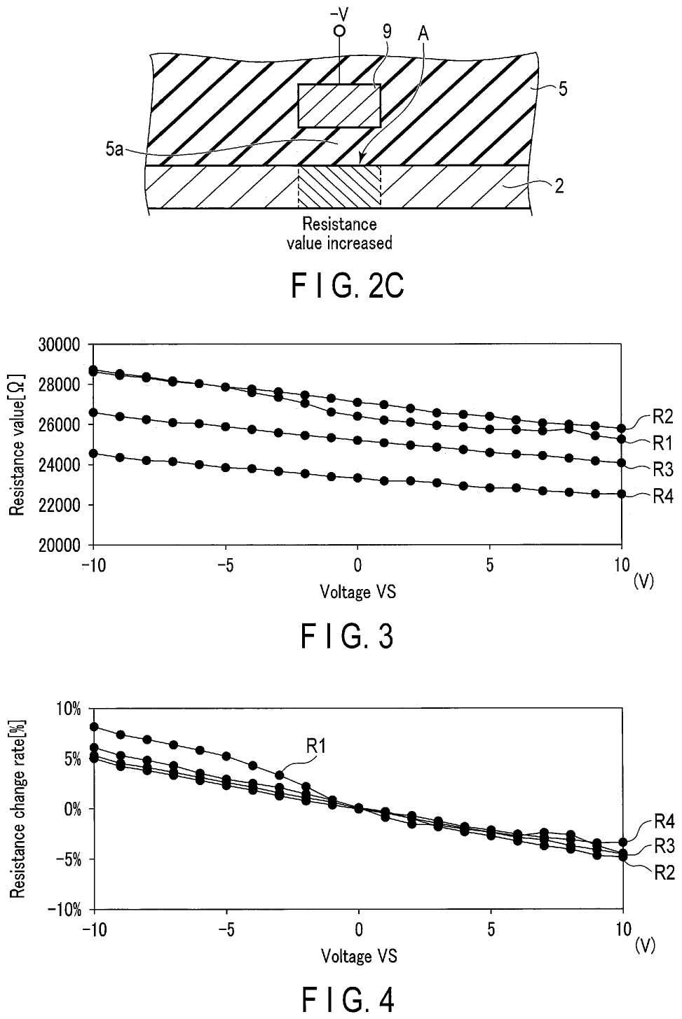

Here, the principle of voltage variation in the voltage-variable type memory element will be described with reference to FIGS. 2A, 2B and 2C to FIG. 4.

FIG. 2A shows an arrangement example of an electrode 9 which is arranged so as to face the semiconductor wiring 2 via the interlayer insulating layer 5a in proximity to the semiconductor wiring 2. Here, in order to make the description easy to understand, the description will be made while the charge storage layer 3 of the voltage-variable type memory element 1 is replaced with the electrode 9. Here, the following description will be made on an example in which a freely settable reference potential is set to 0 V, and a positive potential (or positive voltage) and a negative potential (or negative voltage) are applied to the reference potential.

As shown in FIG. 2B, when a positive voltage was applied to the electrode 9, there was obtained a measurement result of reducing the resistance value which indicated that the resistance value of a region A of the semiconductor wiring 2 facing the electrode 9 was lower than a reference resistance value under the reference potential (under application of 0 V). Conversely, as shown in FIG. 2C, for example, when a negative voltage was applied to the electrode 9, there was obtained a measurement result of increasing the resistance value which indicated that the resistance value of the region A of the semiconductor wiring 2 was higher than the reference resistance value. It is estimated that the change of the resistance value in these measurement results is caused by an influence of hot carriers and the like.

FIG. 3 shows an example of changes of the resistance values of four semiconductor wirings R1 to R4 in the structure of the semiconductor wiring 2 and the electrode 9 shown in FIG. 2A. The resistance values in this example are not specified values, but are numerical values which appropriately vary depending on the material of the semiconductor wiring, the concentration of impurities, etc. In this case, the magnitude relation of the resistance values and the inclination directions of characteristic lines are presented.

FIG. 3 shows changes of the resistance value of the semiconductor wiring 2 obtained when a voltage VS of −10 V to +10 V was applied to the electrode 9 so as to be swept with respect to the semiconductor wirings R1 to R4. Each of these semiconductor wirings R1 to R4 has an inclination in which the resistance value decreases substantially linearly from −10 V to +10 V. In this example, the range of the change in resistance value between −10 V and +10 V is about 2000Ω. In a practical range, for example, between −5 V and +5 V, a difference in resistance value of about 800Ω occurs for each of the semiconductor wirings R1 to R4. Note that FIG. 3 characteristically shows the change of the resistance value of the semiconductor wiring 2, and the resistance values on the vertical axis are influenced by the concentration of the impurities or the like, and are not limited numerical values.

In the embodiment described below, an example of charging to potentials on both the positive and negative sides with application of 0 V (no application) as a reference will be described, but only 0V is not limited as a reference. In other words, a setting range only on the positive potential side in which a potential difference of, for example, +1 V and +9 V or the like with +5 V as a reference may be provided. Conversely, a setting range only on the negative potential side, that is, a setting range having a negative reference potential and a potential difference of upper and lower potentials centered on the reference potential may be provided. When it is determined based on two values of high and low levels whether data is stored or not, a voltage range to be set is not necessarily required to span positive and negative voltages. In other words, it is not necessary to set the center of the voltage range to 0 V, and it is possible to set a voltage range with two values which provide a potential difference, for example, +1V and +9 V or the like on a range only on the positive potential side (or only on the negative potential side). Note that the example in which it is determined based on binary levels of high and low levels whether data is stored or not is described here, but the present invention is not necessarily limited to two values, and it is possible to carry out multi-value determination by setting a plurality of voltage values, that is, setting a plurality of determination levels.

FIG. 4 shows resistance change rates calculated based on the changes of the resistance values of the semiconductor wirings R1 to R4 obtained in FIG. 3. In the resistance change rates, the tendencies of the resistance change rates of the semiconductor wirings R1 to R4 substantially coincide with one another with application of 0 V (no application) as a reference. In a practical range, for example, between −5 V and +5 V, a resistance change rate of about 5% occurs.

As described above, when a voltage is applied to the electrode which is adjacent through the insulator to the semiconductor wiring 2 whose resistance value has been reduced by the processing of doping impurities or the like, a result indicating that the resistance value of the semiconductor wiring 2 changes is obtained.

The change of increase or decrease in the resistance value of the semiconductor wiring 2 causes a voltage variation with respect to a reading signal (a data estimation signal Vd described later) flowing through the semiconductor wiring 2. In other words, when a positive or negative voltage is applied to the electrode 9 to cause a change in resistance value of the semiconductor wiring 2 in a state where a voltage of a certain value is applied to the semiconductor wiring 2, the value of the voltage of the signal flowing through the semiconductor wiring 2 is changed.

Therefore, in the voltage-variable type memory element, the resistance value of the semiconductor wiring arranged adjacently to the charge storage layer is changed according to whether data is written in the charge storage layer, that is, the charged state of a negative potential or the charged state of a positive potential in the charge storage layer. The change of the resistance value varies the current or voltage of a signal flowing through the semiconductor wiring. Therefore, by detecting the voltage variation of the reading signal (data estimation signal Vd) passing through the semiconductor wiring, it can be detected whether data has been written in the charge storage layer. The voltage-variable type memory element outputs whether data has been stored in the charge storage layer without reading out the data itself stored in the charge storage layer.

Next, a voltage-variable type memory element using change in resistance value of the semiconductor wiring will be described. The voltage variations of data estimation signals Vd1 and Vd2 caused by the change of the resistance value of the semiconductor wiring 2 in the voltage-variable type memory element 1 will be described with reference to FIG. 1 and FIGS. 5 to 8.

First, at an initial stage of the voltage-variable type memory element 1 shown in FIG. 1, no voltage is applied from the semiconductor wiring 2 or the electrode 4, and the charge storage layer 3 has no information (charges) to be stored and is set to a floating potential. Here, it is assumed that the semiconductor wiring 2 is formed of polysilicon having a low resistance value into which arbitrary impurities are doped. The low resistance value is also a resistance value under application of no voltage.

[Data Writing]

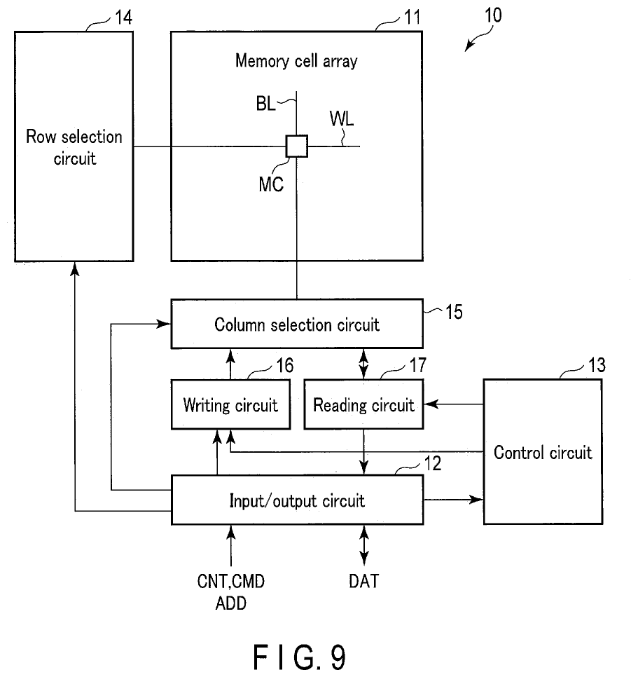

As shown in FIG. 5, the electrode 4 is set to a potential of 0 V by a writing circuit 16 (FIG. 9) described later, and a writing voltage Vpgm is applied to the semiconductor wiring 2 to write information in the charge storage layer 3. The writing voltage Vpgm has a high voltage value of, for example, about 12 V to about 24 V at the maximum. The charge storage layer 3 in which the information has been written falls into a state where it has been injected with electrons and charged to a negative potential.

[Data Erasure]

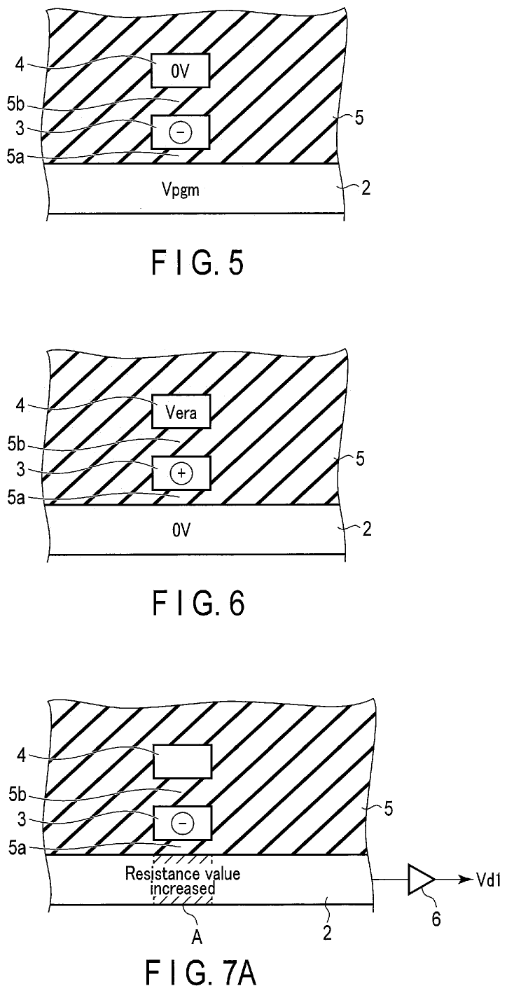

As shown in FIG. 6, when the information stored in the charge storage layer 3 is erased, the semiconductor wiring 2 is set to a potential of 0 V by a reading circuit 17 (FIG. 9) described later, and also a data erasing voltage Vera is applied to the electrode 4. The stored electrons are discharged from the charge storage layer 3, so that the charge storage layer 3 falls into a state where it has been charged to a positive potential.

[Data Reading 1 (Stored Information is Present)]

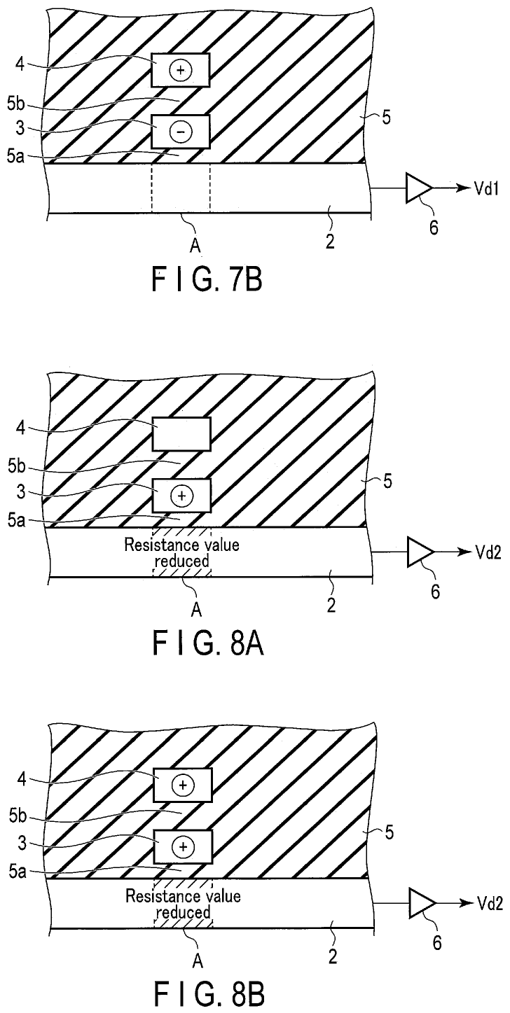

When the charge storage layer 3 of the voltage-variable type memory element 1 has been charged to a negative potential, as shown in FIG. 7A, a wiring region A of the semiconductor wiring 2 which faces the charge storage layer 3 falls into a state where the resistance value thereof has been increased. At this time, the potential of the electrode 4 is brought into a floating state.

As shown in FIG. 7B, under a state where a positive voltage (for example, a read voltage Vread described later) for preventing reading is applied to the electrode 4, negative charges (electrons) which have been charged in the charge storage layer 3 are attracted to the electrode 4 side, and the wiring region A of the semiconductor wiring 2 is not affected by the negative charges. Therefore, the wiring region A is not increased in resistance value, and falls into a state where the resistance value thereof has been reduced as in the case where the charge storage layer 3 is not charged with a voltage. The data estimation signal passing through the semiconductor wiring 2 suffers a smaller voltage drop than that in the case of the high resistance value. At this time, a signal which has passed by inputting a data estimation signal Vd corresponding to a Bit signal described later into the semiconductor wiring 2 maintains the signal voltage thereof (high level) and is output as a data estimation signal Vd1 indicating that stored data is present.

[Data Reading 2 (Stored Information is Absent)]

When the charge storage layer 3 of the voltage-variable type memory element 1 has been charged to a positive potential, the wiring region A of the semiconductor wiring 2 which faces the charge storage layer 3 falls into a state where it has been reduced in resistance value as shown in FIG. 8A. At this time, the potential of the electrode 4 is set to a floating state. At this time, a signal which has passed by inputting the data estimation signal Vd corresponding to the Bit signal described later into the semiconductor wiring 2 is reduced in the signal voltage thereof (low level) and is output as a data estimation signal Vd2 (Vd1>Vd2) indicating that stored data is absent.

As shown in FIG. 8B, even under a state where a positive voltage (for example, the read voltage Vread described later) for preventing reading is applied to the electrode 4, the wiring region A of the semiconductor wiring 2 maintains a resistance-value-reduced state by the positive charges charged in the charge storage layer 3. This indicates that in a memory cell array 11 described later, even when the read voltage Vread is applied to the electrode 4 (word line BL) under a state where data is stored in a non-selected memory cell MC, the reduction in resistance value is maintained, and thus the resistance value of the semiconductor wiring 2 (bit line BL) is not increased.

As described above, the voltage-variable type memory element 1 according to the present embodiment increases or reduces the resistance values of semiconductor wirings arranged in proximity to one another by the accumulation of positive and negative charges, that is, the presence or absence of stored data. The data estimation signal Vd is made to flow through the semiconductor wiring whose resistance value changes, and the data estimation signals Vd1 and Vd2 of two levels based on the variation of the voltage of the signal can be obtained. These data estimation signals Vd1 and Vd2 are amplified, and compared with a preset threshold value to determine “0” or “1” which is a data output signal DAT. Alternatively, any one of the data estimation signals (Vd1 or Vd2) may be set as a reference value, and the determination may be made by directly comparing the data estimation signal Vd1 and the data estimation signal Vd2 with each other.

Accordingly, only by making the data estimation signal flow through a selected semiconductor wiring when stored information is read out, it can be checked whether charges serving as information has been stored in the charge storage layer 3. Since data transfer is not performed on the charge storage layer 3, the data reading operation is fast. Furthermore, since electrons do not move through the interlayer insulating layer (corresponding to a gate insulating film or a tunnel oxide film in the case of an NAND type flash memory) when data is read out, it is possible to delay progress of deterioration of the interlayer insulating layer.

### Second Embodiment

An example of a semiconductor memory device using a voltage-variable type memory element 1 as a memory cell (MC) will be described as a second embodiment.

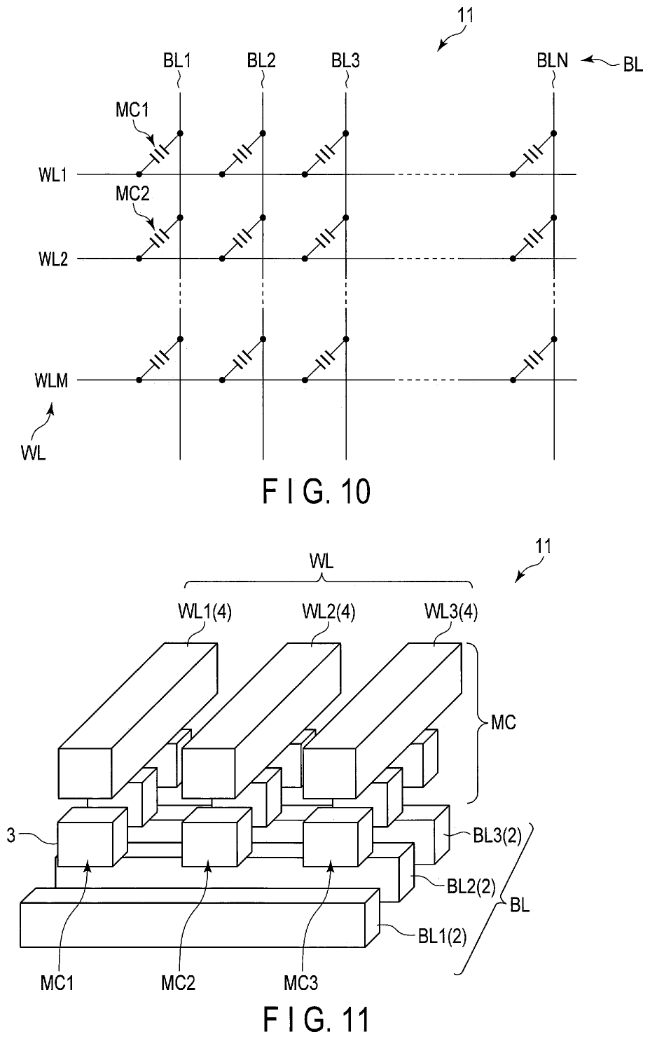

FIG. 9 shows a conceptual overall configuration of a semiconductor memory device 10. FIG. 10 is a diagram conceptually showing a circuit configuration of a memory cell array.

The semiconductor memory device 10 comprises a memory cell array 11, a row selection circuit 14, a column selection circuit 15, a sense amplifier 6, a writing circuit 16, an input/output circuit 12, and a control circuit 13. Note that the components of the semiconductor memory device 10 described above present only the components necessary for the description of the present embodiment, and although not shown, it is assumed that the components include components incorporated in a general semiconductor memory device such as an external controller for outputting various control signals CNT, various commands CMD, address signals ADD, and data (writing data) DAT.

The memory cell array 11 comprises a plurality of voltage-variable type memory elements 1 as memory cells MC, and for example, the memory cells MC are arranged in a matrix form at intersection points between word lines WL (WL1 to WEM) and bit lines BL (BL1 to BLN) which are orthogonal to one another as shown in FIG. 10. One memory cell MC is specified by one bit line and one word line. As described above, the word line WL corresponds to the electrode 4, and the bit line BL corresponds to the semiconductor wiring 2.

The word lines WL are associated with rows of the memory cells MC, and the bit lines BL are associated with columns of the memory cells MC. Therefore, a memory cell MC is specified by selection of a row and selection of a column. When data of one memory element is selectively rewritten (erased and written), the one memory element may be selected, or rewriting may be performed while a group containing a memory element to be selected is set as a rewriting unit. For example, a unit of one bit line or one block when arranged memory cells MC are sectioned into a plurality of blocks BLK as in the case of an NAND flash memory may be used as a data erasing unit.

In the case of rewriting data on a group or block basis, after original data are once read out and evacuated and data of all memory elements in a group or a block are erased, rewriting data in which new data are added to the original data may be stored in the group or block. As another method, it is also possible to rewrite data by directly overwriting without performing comparison or erasure on data currently stored in a memory element.

The input/output circuit 12 manages input and output of signals, etc. between each component in the memory device and an external component, receives, for example, various control signals CNT, various commands CMD, address signals ADD, and data (writing data) DAT from an external controller, and transmits data (reading data) DAT to the external controller.

The control circuit 13 receives a control signal CNT and a command CMD from the input/output circuit 12. The control circuit 13 controls each component based on control instructed by the control signal CNT and the command CMD. For example, the control circuit 13 controls the row selection circuit 14 and the column selection circuit 15 to select a memory cell MC on which data writing, data erasure, or data reading is performed. The control circuit 13 instructs the writing circuit 16 and the reading circuit 17 to apply a data writing voltage Vpgm, a data erasing voltage Vera, etc. described later. Furthermore, the control circuit 13 supplies a power supply voltage for driving each component at an appropriate timing.

The row selection circuit 14 selects one memory cell MC or one block BLK based on an address signal ADD received from the input/output circuit 12. Thereafter, the row selection circuit 14 applies, for example, a predetermined voltage, for example, the data erasing voltage Vera (erasure signal) or a non-selection voltage (Vread) (non-selection signal) to each of a selected word line WL and non-selected word lines WL.

The column selection circuit 15 brings a bit line specified from among a plurality of bit lines BL corresponding to the columns into a selected state based on the address signal ADD received from the input/output circuit 12. For example, one memory cell MC or one block BLK is selected.

The writing circuit 16 receives writing data DAT from the input/output circuit 12 and supplies the data writing voltage Vpgm (data writing signal) to the column selection circuit 15 based on the control of the control circuit 13 and the writing data DAT.

The reading circuit 17 includes the sense amplifier 6. The reading circuit 17 inputs the data estimation signal Vd to the selected bit line BL based on the control of the control circuit 13, and amplifies a passing signal by the sense amplifier 6 to generate the data estimation signals Vd1 and Vd2. Here, the data estimation signal Vd1 suggests a data output signal “1” containing stored information (data), and the data estimation signal Vd2 suggests a data output signal “0” containing no stored information. The reading circuit 17 converts the data estimation signal Vd1 to “1” and the data estimation signal Vd2 to “0”, and outputs them as a data output signal DAT to the input/output circuit 12.

Next, the operation of the semiconductor memory device using the voltage-variable type memory element 1 will be described with reference to FIG. 11 to FIG. 14. Although not shown, as in the structure shown in FIG. 1 described above, the lamination structure shown in FIG. 11 to FIG. 14 is formed such that a silicon oxide film or the like is filled as an interlayer insulating layer among each bit line BL, each charge storage layer 3, and each word line WL.

FIG. 11 is a diagram showing an example of a three-dimensional lamination structure of memory cells (MC) each comprising a voltage-variable type memory element. This memory cell array 11 has a lamination structure corresponding to a circuit diagram shown in FIG. 10.

In this memory cell array 11, a plurality of bit lines BL (BL1 to BLN) [third layer] are arranged in parallel in a lower layer. Charge storage layers 3 [second layer] are arranged at equal intervals above the bit lines BL via an interlayer insulating layer. The charge storage layer 3 has a rectangular parallelepiped shape, and the length of the side is substantially equal to or does not exceed the width of the bit line BL and the width of the word line WL. The thickness of the charge storage layer 3 is appropriately set according to the amount of charges required for reducing the resistance value and increasing the resistance value based on the design.

Furthermore, a plurality of word lines WL (WL1 to WLM) [first layer] are arranged in a layer above the charge storage layers 3 via an interlayer insulating layer in a direction orthogonal to the plurality of bit lines BL. In such an arrangement, the charge storage layers 3 are arranged to be interposed between the respective intersection points of the bit lines BL and the word lines WL to form the memory cells MC (MC1, MC2, MC3, etc.). As described above, in the voltage-variable type memory element 1, the word line WL corresponds to the electrode 4, and the bit line BL corresponds to the semiconductor wiring 2.

[Data Writing]

Next, writing of data into the memory cell MC2 of the memory cell array 11 will be described with reference to FIG. 11 and FIG. 5.

First, a memory cell into which data is to be written is selected. Here, an example in which the memory cell MC2 is selected to write data will be described. When the memory cell MC2 is selected, the potentials of the word lines WL1, WL3, etc. other than the word line WL2 hanging over the memory cell MC2 are set to a floating state. In addition to this setting, the potentials of the bit lines BL2, BL3, etc. other than the bit line BL1 hanging over the memory cell MC2 are set to a floating state.

Next, as described with reference to FIG. 5, the word line WL2 is set to a reference potential [second voltage], for example, 0 V, and a data writing signal is supplied to the bit line BL1 to apply a data writing voltage Vprgm [third voltage]. At this time, electrons (negative charges) are injected from the word line WL2 into the charge storage layer 3 of the memory cell MC2 and trapped, so that the charge storage layer 3 is set to a negative potential. In the memory cell MC2, a state where the charge storage layer 3 has a negative potential is defined as a state where data has been written.

At this time, as shown in FIG. 7A, the charge storage layer 3 charged with negative charges increases the resistance value of the region A which is a part of the opposite bit line BL1.

[Data Erasure]

Next, data erasure in the memory cell MC2 of the memory cell array 11 will be described with reference to FIG. 11 and FIG. 6. FIG. 13 is a diagram showing data erasure of a memory cell (MC) comprising a voltage-variable type memory element.

First, a memory cell on which data erasure is performed is selected. Here, an example in which the memory cell MC2 is selected to erase data will be described. When the memory cell MC2 is selected, the potentials of the word lines WL1, WL3, etc. other than the word line WL2 hanging over the memory cell MC2 are set to a floating state. Along with this setting, the potentials of the bit lines BL2, BL3, etc. other than the bit line BL1 hanging over the memory cell MC2 are set to a floating state.

As described with reference to FIG. 6, the bit line BL1 is set to a reference potential [fourth voltage], for example, 0 V, and a data erasing voltage Vera [fifth voltage] of a positive potential which is an erasing signal is applied to the word line WL2. Holes (positive charges) are supplied to the charge storage layer 3 by the data erasing voltage Vera. With respect to the charge storage layer 3, negative charges that have been charged are discharged to the word line WL2, and instead, positive charges are charged. In the memory cell MC2, a state where the charge storage layer 3 has a positive potential is defined as a state where data has been erased. At this time, as shown in FIG. 7B, the charge storage layer 3 charged with positive charges reduces the resistance value of the region A which is a part of the opposite bit line BL1.

[Data Reading (Stored Data is Present)]

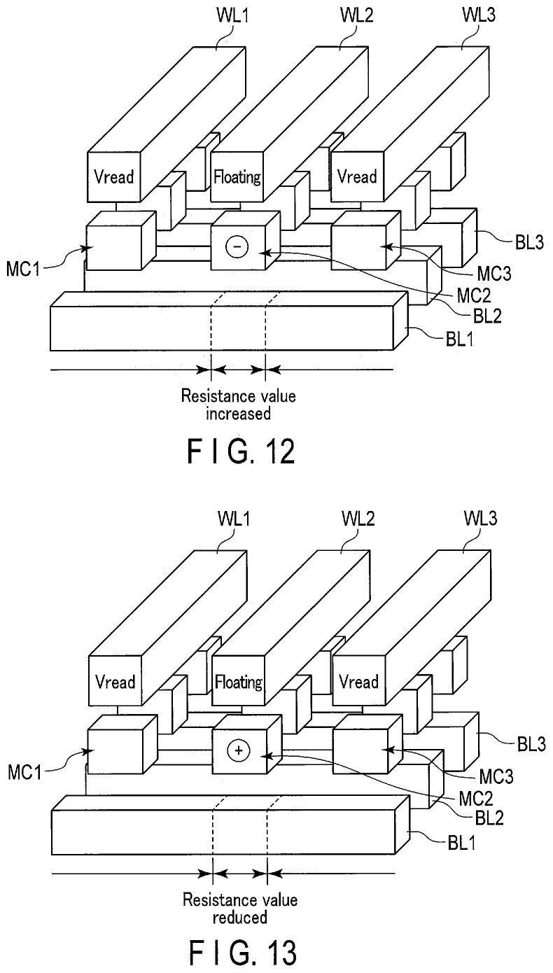

Next, reading of data from the memory cell MC2 of the memory cell array 11 comprising the voltage-variable type memory element will be described. FIG. 12 is a diagram explaining data writing into a memory cell (MC).

In a state where data has been stored in the memory cell MC2, the charge storage layer 3 has charged with negative charges. In other words, the memory cell MC2 increases the resistance value of the region A of the bit line BL1 when the word line WL2 is in the floating state.

First, the memory cell MC2 from which data is read out is selected. Here, an example in which the memory cell MC2 is selected to read data will be described. When the memory cell MC2 is selected, a read voltage Vread [first voltage] having a preset voltage value is applied to non-selected word lines WL1, WL3, etc. other than the word line WL2 hanging over the memory cell MC2. Along with this setting, the potentials of non-selected bit lines BL2, BL3, etc. other than the bit line BL1 hanging over the memory cell MC2 are set to the floating state. This setting increases the resistance value of the region A of the bit line BL1.

After the memory cell MC2 is selected, the data estimation signal Vd is supplied to the bit line BL1. The data estimation signal Vd which has passed through the bit line BL1 suffers a voltage drop by the high resistance value of the region A, so that it is output as the data estimation signal Vd1 as shown in FIG. 7A. At this time, the data estimation signal Vd does not act on the charge storage layer 3, and neither injects nor extracts negative charges (electrons) through the tunnel oxide film as in the case of the NAND flash memory.

[Data Reading (Stored Data is Absent)]

Next, reading of data from the memory cell MC2 of the memory cell array 11 will be described with reference to FIG. 13.

In a state where no data has been stored in the memory cell MC2 (in an erased state), the charge storage layer 3 has been charged with positive charges. In other words, the memory cell MC2 reduces the resistance value of the region A of the bit line BL1 when the word line WL2 is in the floating state.

First, in the same manner described above, the memory cell MC2 from which data is read out is selected. In other words, the read voltage Vread [first voltage] is applied to the non-selected word lines WL1, WL3, etc., and the potentials of the non-selected bit lines BL2, BL3, etc. are set to the floating state.

After the memory cell MC2 is selected, data estimation signal Vd is supplied to the bit line BL1. The data estimation signal Vd which has passed through the bit line BL1 suffers a small voltage drop by the low resistance value of the region A, so that it is output as the data estimation signal Vd2 as shown in FIG. 8A. In this case, the data estimation signal Vd also does not act on the charge storage layer 3, and neither injects nor extracts negative charges (electrons) through the tunnel oxide film as in the case of the NAND flash memory.

[Data Reading Under a Mixture Condition of the Presence and Absence of Data]

In the examples shown in FIGS. 12 and 13, the reading operation has been described by paying attention to only the memory cell MC2 and exemplifying the state where data is present or absent. However, in practice, data are often stored in other memory cells MC on the same bit line.

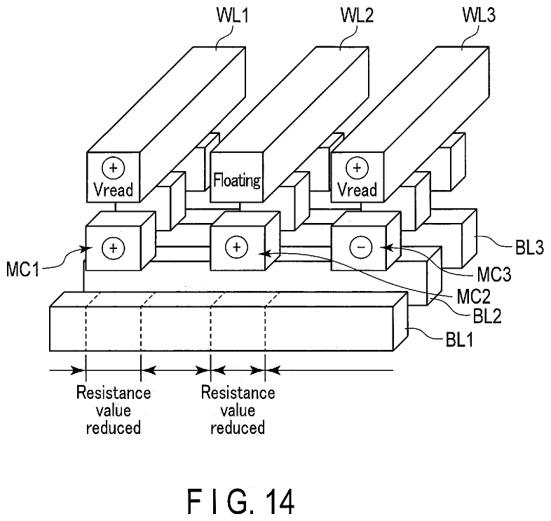

Therefore, an example in which information is read out from one memory cell in a state where data have been stored in a plurality of memory cells MC will be described with reference to FIG. 14.

Here, it is assumed that data have been stored in the memory cell MC2 and the memory cell MC3, and no data has been stored in the memory cell MC1. An example in which data is read out from the memory cell MC2 will be described.

In the same manner as described above, a memory cell MC is selected. In other words, the positive read voltage Vread is applied to the non-selected word lines WL1, WL3, etc., and the potentials of the non-selected bit lines BL2, BL3, etc. are set to the floating state.

At this time, if the non-selected memory cell MC1 is in a state where it has not stored any data and the positive read voltage Vread has been applied to the word line WL1, the non-selected memory cell MC1 has a lower resistance value as shown in FIG. 3 even under application of the positive read voltage Vread. Therefore, a partial region of the bit line BL1 which the charge storage layer of the memory cell MC1 faces falls into a state where the resistance value thereof has been reduced. Therefore, when the data estimation signal Vd is made to flow through the bit line BL1, no voltage drop occurs in the memory cell MC1.

Furthermore, since data has been stored in the non-selected memory cell MC3, if the word line WL3 is in the floating state, a partial region of the bit line BL1 which the charge storage layer of the memory cell MC3 faces would fall into a state where the resistance value thereof has been increased as shown in FIG. 7A. However, as shown in FIG. 14, in a state where the positive read voltage Vread has been applied to the word line WL3, negative charges (electrons) charged in the charge storage layer are attracted to the word line WL3 side. As a result, a partial region (region A) of the bit line BL1 is not affected by the negative charges, and thus the resistance value thereof is not increased. Therefore, even in the case where data has been stored in memory cell MC3 when the data estimation signal Vd is made to flow through the bit line BL1, no voltage drop occurs in the data estimation signal Vd if the memory cell MC3 is not selected.

If the selected memory cell MC2 is in a state where data has been stored therein, the memory cell MC2 would increase the resistance value of the region A of the bit line BL1 when the word line WL2 is in the floating state. Therefore, when the data estimation signal Vd is made to flow through bit line BL1, a voltage drop occurs in the data estimation signal Vd because data has been stored in the memory cell MC2, and the data estimation signal Vd1 indicating that data has been stored is output.

From the foregoing, regardless of the presence or absence of stored data, the non-selected memory cell MC does not increase the resistance value from the original resistance value to a higher resistance value for the bit line BL, and does not have an influence of the voltage drop caused by the high resistance value on the data estimation signal Vd. Therefore, by selecting the memory cell of the memory cell array 11, there is no erroneous output caused by the voltage drop, and appropriate output data can be obtained.

As described above, according to the voltage-variable type memory element of the present embodiment, whether data has been stored in the memory cell can be determined only by supplying the data estimation signal to the bit line and detecting the voltage variation caused by the voltage drop. Furthermore, when the read voltage being currently used is increased due to an improvement of the reading circuit, etc., input/output of data is performed on the charge storage layer of the memory cell from the word line WL, and an effect of securing a long product life appears remarkably without damaging the interlayer insulating layer between the charge storage layer and the bit line BL.

The embodiments and modifications of the present invention described above are not limited. At the implementation stage, various modifications can be made without departing from the subject matter of the invention. Furthermore, the embodiments described above include inventions of various stages, and various inventions are extracted by appropriate combinations of a plurality of disclosed components. When the problem described in the column of the problem to be solved by the invention can be solved and the effect described in the column of the effect of the invention is obtained irrespective of removal of some components from all the components shown in the embodiments, a configuration from which these components are removed is extracted as an invention.

What is claimed is:

1. A voltage-variable type memory element comprising:
an electrode;
a charge storage layer that is arranged on the electrode via a first interlayer insulating layer and stores charges; and
a semiconductor wiring which has electric conductivity, that is arranged on the charge storage layer via a second interlayer insulating layer, and comprises a region facing the charge storage layer, a resistance value of the region being variable according to magnitude of potential corresponding to an amount of charges stored in the charge storage layer, and a voltage value of a reading signal supplied and passing through the semiconductor wiring being varied according to the resistance value.

2. The voltage-variable type memory element according to claim 1, wherein in a case where the electrode is in an electrically floating state, the resistance value of the region of the semiconductor wiring is increased when the potential of the charge storage layer is a high potential with respect to a predetermined reference potential, and reduced when the potential of the charge storage layer is a low potential with respect to the predetermined reference potential, whereby the voltage value of the reading signal flowing through the semiconductor wiring drops according to the resistance value.

3. The voltage-variable type memory element according to claim 1, wherein when the charge storage layer is at a negative potential and a positive voltage is applied to the electrode, electrons in the charge storage layer are attracted to aside of the electrode so that the resistance value of the region of the semiconductor wiring is not increased, thereby suppressing a drop in the region of the voltage value of the reading signal flowing through the semiconductor wiring.

4. The voltage-variable type memory element according to claim 1, wherein the first interlayer insulating layer has a film thickness that prevents charges stored in the charge storage layer from leaking to a side of the electrode and allows writing and erasure of data by charges.

5. The voltage-variable type memory element according to claim 1, wherein the second interlayer insulating layer has a film thickness that prevents charges stored in the charge storage layer from leaking to a side of the semiconductor wiring and allows the stored charges to change a resistance value of the semiconductor wiring.

6. The voltage-variable type memory element according to claim 1, wherein the semiconductor wiring is formed of a conductor including polysilicon that has been doped with impurities to be reduced in resistance value.

7. A semiconductor memory device comprising:
a memory cell array that comprises, as memory cells, a plurality of voltage-variable type memory elements configured by a plurality of word lines arranged in parallel, a plurality of bit lines that intersect the word lines and are arranged in parallel, and a charge storage layer arranged to interpose an interlayer insulating layer between lines at each of intersection positions of the word lines and the bit lines; and
a control circuit that applies a first voltage to a word line associated with a non-selected memory cell, sets a word line associated with a selected memory cell to an electrically floating state, and determines a level of data stored in the selected memory cell based on change of a voltage value of a data estimation signal applied to a bit line associated with the selected memory cell during a reading operation.

8. The semiconductor memory device according to claim 7, wherein a resistance value of the bit line is changed based on magnitude of potential corresponding to an amount of charges stored in the charge storage layer of the selected memory cell, and the data estimation signal is varied to a voltage value corresponding to the resistance value.

9. The semiconductor memory device according to claim 7, wherein during data writing, the control circuit sets a word line and a bit line associated with a non-selected memory cell to an electrically floating state, applies a second voltage to a word line associated with a selected memory cell, and applies a third voltage larger than the second voltage to a bit line associated with the selected memory cell to set the charge storage layer to a negative potential, and during data erasure, the control circuit sets a word line and a bit line associated with a non-selected memory cells to an electrically floating state, applies a fourth voltage to a word line associated with a selected memory cell, and applies a fifth voltage smaller than the fourth voltage to a bit line associated with the selected memory cell to set the charge storage layer to a positive potential.

10. The semiconductor memory device according to claim 7, wherein during reading operation, in a case where data has been stored in a selected memory cell, a region of the bit line which faces the charge storage layer is increased in resistance value by negative charges stored in the charge storage layer when the word line is in the floating state, and a first data output signal in which a voltage value of the data estimation signal passing through the bit line is caused to drop is read out, and in a case where data has not been stored in a selected memory cell, the region of the bit line which faces the charge storage layer is reduced in resistance value by positive charges stored in the charge storage layer when the word line is in the floating state, and a second data output signal in which the voltage value of the data estimation signal passing through the bit line is maintained is read out.
